(19) United States
(12) Patent Application Publication
(10) Pub. No.: US 2023/0397375 A1
(43) Pub. Date: Dec. 7, 2023

(54) COMBINED AIR-COOLING AND LIQUID-COOLING REFRIGERATION SYSTEM AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shuqin FENG, Zhangjiakou City (CN)

(21) Appl. No.: 18/204,966

(22) Filed: Jun. 2, 2023

(30) Foreign Application Priority Data
Jun. 6, 2022 (CN) 202210633816.2

(51) Int. Cl. H05K 7/20; H05K 7/14

(52) U.S. Cl. CPC H05K 7/20745; H05K 7/1497; H05K 7/2079

(57) ABSTRACT

The present disclosure discloses a combined air-cooling and liquid-cooling refrigeration system and a data center, where the combined air-cooling and liquid-cooling refrigeration system includes a closed area, a combined device group, and a circulating liquid-cooling system. The combined device group and the circulating liquid-cooling system are installed in the closed area. The combined device group includes a first device group and a second device group, and a closed thermal channel is formed between the first device group and the second device group. The first device group and the second device group each include a plurality of air cooling devices and a plurality of heating devices. The circulating liquid-cooling system is connected to primary heating sources of the plurality of heating devices, and the plurality of air cooling devices refrigerate hot air discharged from the closed thermal channel.

### CROSS-REFERENCE TO RELATED APPLICATION

This application claims priority to Chinese Patent Application No. 202210633816.2, titled “COMBINED AIR-COOLING AND LIQUID-COOLING REFRIGERATION SYSTEM AND DATA CENTER” and filed to the China National Intellectual Property Administration on Jun. 6, 2022, the entire contents of which are incorporated herein by reference.

### TECHNICAL FIELD

The present disclosure relates to the field of data center, and more particularly, to a combined air-cooling and liquid-cooling refrigeration system and a data center.

### BACKGROUND

In recent years, with the rapid development of data center related technologies, centralized configuration of computer room servers, together with servers and storage systems, has changed, and their power density and heat density have increased rapidly, resulting in a surge in heat generated by data centers, which leads to higher and higher requirements of the data centers for refrigeration systems.

For the existing data centers, using single air-cooling air conditioners or single liquid-cooling radiators can no longer meet the refrigeration requirements of the high-density data centers.

### SUMMARY

An objective of the present disclosure is to provide a combined air-cooling and liquid-cooling refrigeration system and a data center, to improve heat dissipation efficiency.

To achieve the above objective, one aspect of the present disclosure provides a combined air-cooling and liquid-cooling refrigeration system, which at least includes a closed area, a combined device group, and a circulating liquid-cooling system. The combined device group and the circulating liquid-cooling system are installed in the closed area. The combined device group includes a first device group and a second device group, and a closed thermal channel is formed between the first device group and the second device group. The first device group and the second device group each include a plurality of air cooling devices and a plurality of heating devices. The circulating liquid-cooling system is connected to primary heating sources of the plurality of heating devices to carry out liquid-cooling heat dissipation on the primary heating sources of the plurality of heating devices, and the plurality of air cooling devices refrigerate hot air discharged from the closed thermal channel to carry out air-cooling heat dissipation on the heating devices.

As a further improvement of the above technical solutions, the plurality of air-cooling devices and the plurality of heating devices positioned in the same device group are arranged alternately in turn; and the plurality of air cooling devices of the first device group and the plurality of heating devices of the second device group are arranged opposite to each other.

As a further improvement of the above technical solutions, the first device group and the second device group are arranged in parallel at intervals; and partition plates are respectively arranged between two ends of the first device group and the second device group, such that the closed thermal channel is formed between the first device group, the second device group, and the two partition plates.

As a further improvement of the above technical solutions, the circulating liquid-cooling system comprises at least a liquid inlet pipe, a liquid outlet pipe and a plurality of liquid-cooling shunts. The liquid inlet pipe and the liquid outlet pipe are connected to an external cooling device to refrigerate circulating liquid in the liquid inlet pipe and the liquid outlet pipe. One end of each of the plurality of liquid-cooling shunts is communicated with the liquid inlet pipe, and other end of each of the plurality of liquid-cooling shunts is communicated with the liquid outlet pipe. Each of the plurality of liquid-cooling shunts is connected in series with one end of a heat transfer component, and other end of the heat transfer component is in contact with the primary heating source of the heating device.

As a further improvement of the above technical solutions, the heat transfer component comprises at least a heat exchange box, a male contact head, and a female contact head. The heat exchange box is connected in series with the liquid-cooling shunt, such that the circulating liquid in the liquid-cooling shunt flows through an internal cavity of the heat exchange box. The male contact head is connected to the heat exchange box, and one end of the male contact head is positioned in the internal cavity of the heat exchange box. One end of the female contact head is detachably connected to other end of the male contact head, and other end of the female contact head is in contact with the primary heating source of the heating device.

As a further improvement of the above technical solutions, the other end of the female contact head is provided with a plurality of heat conduction bars, and the plurality of heat conduction bars are respectively connected to at least one of the primary heating sources.

As a further improvement of the above technical solutions, the circulating liquid-cooling system further comprises a heat exchanger, and the external cooling device exchanges heat with the circulating liquid in the liquid inlet pipe and the liquid outlet pipe through the heat exchanger.

As a further improvement of the above technical solutions, the heat exchanger is provided at one end of the first device group and one end of the second device group; and an array cabinet is provided at other end of the first device group and other end of the second device group.

As a further improvement of the above technical solutions, there are a plurality of the combined device groups, and the plurality of combined device groups are arranged in the closed area in a linear array.

To achieve the above objective, another aspect of the present disclosure also provides a data center, which comprises at least a plurality of device rooms, where each of the plurality of device rooms is provided with the combined air-cooling and liquid-cooling refrigeration system.

As can be seen, according to the technical solutions provided by the present disclosure, by connecting the circulating liquid-cooling system to a main heating source of the heating device, liquid cooling is carried out on the main heating source of heating device. Furthermore, a combined device group is arranged in the closed area, and the first device group and the second device group form a closed thermal channel, such that hot air generated by the heating device in the closed thermal channel can be cooled by the air cooling device, thereby forming cold environment in the closed area to dissipate heat from the rest of heating sources of the heating device. In this way, heat is dissipated from the main heating source by means of liquid cooling, and heat is dissipated from the rest of heating sources by means of air cooling, such that air cooling and liquid cooling is integrated, which can effectively improve heat dissipation efficiency and meet heat dissipation requirements.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a combined air-cooling and liquid-cooling refrigeration system according to an embodiment of the present disclosure;

FIG. 2 is a schematic diagram showing a partial structure of FIG. 1; and

FIG. 3 is a schematic diagram showing connection between a circulating liquid-cooling system and a heat transfer component according to an embodiment of the present disclosure.

Reference numerals in the figures: closed area 1; combined device group 2; first device group 21; air cooling device 211; heating device 212; second device group 22; closed thermal channel 23; partition plate 24; circulating liquid-cooling system 3; liquid inlet pipe 31; liquid outlet pipe 32; liquid-cooling shunt 33; heat exchanger 34; array cabinet 35; heat transfer component 4; heat exchange box 41; male contact head 42; female contact head 43; and heat conduction bar 431.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

Centralized configuration of computer room servers, together with servers and storage systems, has changed, and their power density and heat density have increased rapidly, resulting in a surge in heat generated by data centers, which leads to higher and higher requirements of the data centers for refrigeration systems.

The existing data centers use single air-cooling air conditioners or single liquid-cooling radiators for refrigeration, but their heat dissipation effects can no longer meet the refrigeration requirements of the high-density data centers. Therefore, the present disclosure provides a combined air-cooling and liquid-cooling refrigeration system and a data center, which integrates air-cooling and liquid-cooling refrigeration to improve the heat dissipation efficiency.

The technical solutions in the embodiment of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

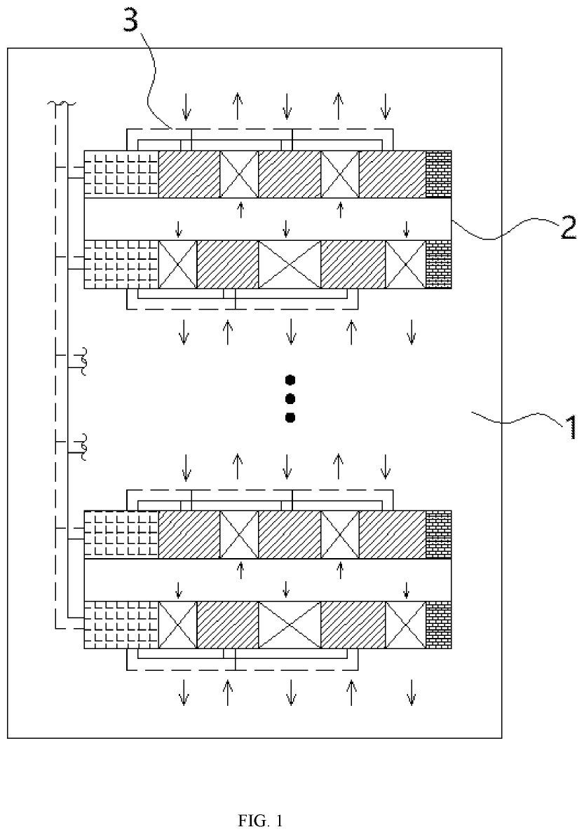

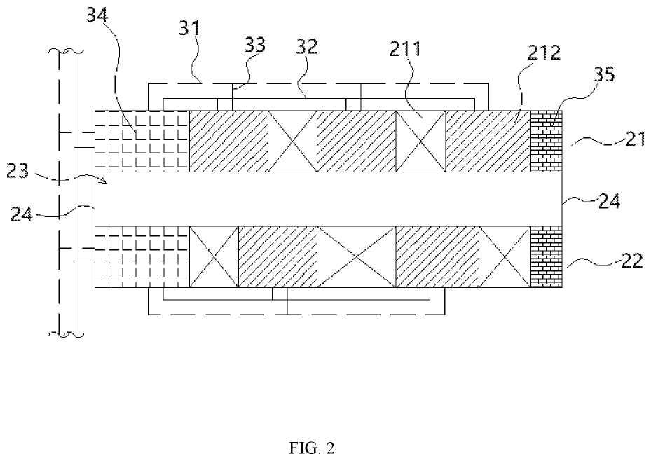

As shown in FIGS. 1 and 2, in an implementable embodiment, a combined air-cooling and liquid-cooling refrigeration system may at least include a closed area 1, a combined device group 2 and a circulating liquid-cooling system 3, where the combined device group 2 and the circulating liquid-cooling system 3 are installed in the closed area 1. The combined device group 2 includes a first device group 21 and a second device group 22, and a closed thermal channel 23 is formed between the first device group 21 and the second device group 22, such that heat generated in the first device group 21 and the second device group 22 flows into the closed thermal channel 23.

The first device group 21 and the second device group 22 each comprise a plurality of air cooling devices 211 and a plurality of heating devices 212. The heating devices 212 may be some devices such as commonly used server cabinets that generate a large amount of heat during normal operation. The air cooling device 211 is configured to refrigerate hot air flowing out of the closed thermal channel 23, to maintain a cold environment in the closed area 1, thereby dissipating heat from heating elements in the heating device 212. The circulating liquid-cooling system 3 is connected to primary heating sources (such as CPU, GPU and so on in a server cabinet) of the plurality of heating devices 212 to carry out liquid-cooling heat dissipation on the primary heating sources of the plurality of heating devices 212, and the plurality of air cooling devices 211 refrigerate the hot air discharged from the closed thermal channel 23 to carry out air-cooling heat dissipation on the heating devices 212.

In practical use, the combined air-cooling and liquid-cooling refrigeration system may be applied to heat dissipation of server cabinets in data centers. Correspondingly, the air cooling devices 211 may be inter-row air conditioners, and the heating devices 212 may be server cabinets. The circulating liquid-cooling system 3 is configured to dissipate heat from the CPU and the GPU in the server cabinet. The heat generated by the server cabinet in the combined device group 2 heats the air to form hot air, which enters the closed thermal channel 23, thereby cooling the air through the air cooling device 211, lowering the entire air temperature, and further cooling the rest of heating components of the server cabinet.

It should be pointed out that although in the above practical application, the combined air-cooling and liquid-cooling refrigeration system of the present disclosure is applied to the data center to dissipate heat from the server cabinet, but it is not limited thereto. The combined air-cooling and liquid-cooling refrigeration system of the present disclosure may also be applied to other devices other than the data center, to carry out efficient heat dissipation and cooling for the other devices. In addition, the primary heating sources defined in the present disclosure may be determined in advance by technicians, which may be parts or positions with the largest quantity of produced heat in the heating device.

In an implementable embodiment, to improve more efficient heat dissipation, as shown in FIG. 2, a plurality of air cooling devices 211 and a plurality of heating devices 212 positioned in the same device group may be arranged alternately in turn. In this way, it is expectable to avoid heat accumulation of the plurality of heating devices 212, which is disadvantageous to heat dissipation.

Further, the plurality of air cooling devices 211 of the first device group 21 and the plurality of heating devices 212 of the second device group 22 are arranged opposite to each other. Thus, the air-cooling device 211 of one device group may face the heating device of other device group, which can shorten a moving distance of the hot air and quickly cool heating spots.

Formation of a specific structure of the closed thermal channel 23 is described below. In an implementable embodiment the first device group 21 and the second device group 22 are arranged in parallel at intervals. Partition plates 24 are respectively arranged between two ends of the first device group 21 and the second device group 22, such that the closed thermal channel 23 is formed between the first device group 21, the second device group 22, and the two partition plates 24. Of course, in actual use, a bottom surface of the first device group 21 and a bottom surface of the second device group 22 may be provided with a floor plate, and a top surface of the first device group 21 and a top surface of the second device group 22 may be provided with a cover plate, to close upper and lower ends of the closed thermal channel 23.

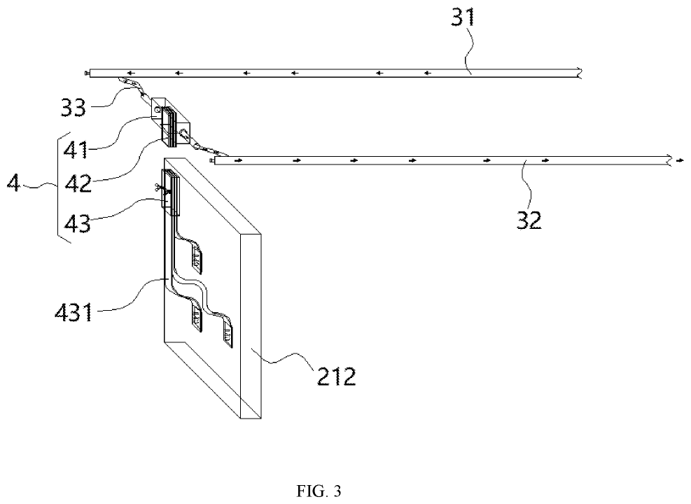

As for the specific structure of the circulating cooling system 3, in an implementable embodiment, referring to FIG. 2 and FIG. 3, the circulating liquid-cooling system 3 may at least include a liquid inlet pipe 31, a liquid outlet pipe 32, and a plurality of liquid-cooling shunts 33. The liquid inlet pipe 31 and the liquid outlet pipe 32 are connected to an external cooling device to refrigerate circulating liquid in the liquid inlet pipe 31 and the liquid outlet pipe 32. One end of each of the plurality of liquid-cooling shunts 33 is communicated with the liquid inlet pipe 31, and other end of each of the plurality of liquid-cooling shunts 33 is communicated with the liquid outlet pipe 32, such that circulating cold water in the liquid inlet pipe 31 enters the liquid-cooling shunt 33, and after heat exchange, hot water in the liquid-cooling shunt 33 flows into the liquid outlet pipe 32, thereby implementing liquid cooling circulation.

Correspondingly, each of the plurality of liquid-cooling shunts 33 may be connected in series with one end of a heat transfer component 4, and other end of the heat transfer component 4 is in contact with the primary heating source of the heating device 212, such that the primary heating source of the heating device 212 can transfer heat to the liquid in the liquid-cooling shunt 33 through the heat transfer component 4 to implement heat exchange.

The specific structure of the heat transfer component 4 is as below: the heat transfer component 4 comprises at least a heat exchange box 41, a male contact head 42, and a female contact head 43. The heat exchange box 41 is connected in series with the liquid-cooling shunt 33, such that the circulating liquid in the liquid-cooling shunt 33 may flow through an internal cavity of the heat exchange box 41. The male contact head 42 is connected to the heat exchange box 41, and one end of the male contact head 42 is positioned in the internal cavity of the heat exchange box 41, such that the male contact head 42 can exchange heat with the liquid in the internal cavity of the heat exchange box 41. One end of the female contact head 43 is detachably connected to other end of the male contact head 42, and other end of the female contact head 43 is in contact with the primary heating source of the heating device 212. Thus, the primary heating source of the heating device 212 can transfer the heat to the internal cavity of the heat exchange box 41 through the female contact head 43 and the male contact head 42 to exchange heat with the liquid in the internal cavity of the heat exchange box 41. Meanwhile, the liquid in the liquid-cooling circulation system is not in direct contact with the heating source, which can effectively avoid damage of the heating device caused by leakage of the liquid.

In practical application, the male contact head 42 may be welded to the heat exchange box 41, and it is ensured that part of one end of the male contact head 42 is positioned within the internal cavity of the heat exchange box 41. Of course, the male contact head 42 may be integrally formed with the heat exchange box 41, which is not specifically limited in the present disclosure. The male contact head 42 and the female contact head 43 may be connected by way of plugging and unplugging to facilitate maintenance and replacement. The male contact head 42 and the female contact head 43 may be made of a thermally conductive material such as copper, iron or the like.

It should be noted that the specific structure of the heat transfer component 4 described above is only one embodiment of the present disclosure, but is not limited thereto. The heat transfer component 4 may also be a circulating duct configured to guide the liquid into the heating device, to attach/cover (or directly soak) the primary heating source, thereby dissipating heat from the primary heating source of the heating device 212.

Further, the other end of the female contact head 43 is provided with a plurality of heat conduction bars 431, and the plurality of heat conduction bars 431 are respectively connected to at least one of the primary heating sources. In this way, one female contact head 43 may be connected to a plurality of heating sources. It should be pointed out that the heat conduction bars 431 may have elasticity, so they can be bent for connection and arrangement, making it convenient for operation.

In one implementable embodiment, the circulating liquid in the liquid inlet pipe 31, the liquid outlet pipe 32 and the liquid-cooling shunt 33 is prevented from being contaminated, thereby preventing internal blockage. In one implementable embodiment, the circulating liquid-cooling system 3 further includes a heat exchanger 34. The external cooling device exchanges heat with the circulating liquid in the liquid inlet pipe 31 and the liquid outlet pipe 32 through the heat exchanger 34.

In practical use, the external cooling device may be a cooling tower and the heat exchanger 34 may be a plate heat exchanger. The plate heat exchanger has outer circulation inlet and outlet and inner circulation inlet and outlet, where the outer circulation inlet and outlet are connected in series with a circulation loop of the external cooling device to form an outer circulation, and the inner circulation inlet and outlet are connected in series with the liquid inlet pipe 31 and the liquid outlet pipe 32 to form an inner circulation. In this way, the liquid in the inner circulation and the liquid in the outer circulation are separated to avoid pollution. Meanwhile, the liquid in the outer circulation may exchange heat with the liquid in the inner circulation through the heat exchanger 34, thereby achieving heat dissipation of the primary heating source of the heating device 212.

Further, the heat exchanger 34 is provided at one end of the first device group 21 and one end of the second device group 22. An array cabinet 35 is provided at other end of the first device group 21 and other end of the second device group 22, where the array cabinet is configured to supply power to the corresponding device group. By distributing the heat exchanger 34 and the array cabinet 35 at two ends of the device group, adverse effects of liquid leakage of the heat exchanger 34 on the array cabinet 35 can be avoided to a certain extent.

Further, there may be a plurality of combined device groups 2, and the plurality of combined device groups 2 are arranged in the closed area 1 in a linear array, such that the air cooling devices 211 of adjacent two device groups 2 can refrigerate each other.

Based on the same inventive concept, the present disclosure also provides a data center, which includes at least a plurality of device rooms, where each of the plurality of device rooms is provided with the combined air-cooling and liquid-cooling refrigeration system.

It is to be particularly point out that reference may be made to the above contents for the specific structure of applying the combined air-cooling and liquid-cooling refrigeration system to the data center, which is not to be described in detail here.

As can be seen, according to the technical solutions provided by the present disclosure, by connecting the circulating liquid-cooling system to a main heating source of the heating device, liquid cooling is carried out on the main heating source of heating device. Furthermore, a combined device group is arranged in the closed area, and the first device group and the second device group form a closed thermal channel, such that hot air generated by the heating device in the closed thermal channel can be cooled by the air cooling device, thereby forming cold environment in the closed area to dissipate heat from the rest of heating sources of the heating device. In this way, heat is dissipated from the main heating source by means of liquid cooling, and heat is dissipated from the rest of heating sources by means of air cooling, such that air cooling and liquid cooling is integrated, which can effectively improve heat dissipation efficiency and meet heat dissipation requirements.

Meanwhile, the plurality of air-cooling devices and the plurality of heating devices positioned in the same device group are arranged alternately in turn; and the plurality of air cooling devices of the first device group and the plurality of heating devices of the second device group are arranged opposite to each other. In this way, gas in the combined device group can circulate, which accelerates heat dissipation effects.

Furthermore, the heat transfer component adopts the male contact head and the female contact head to exchange heat of the primary heating source with the circulating liquid, to avoid direct contact with the primary heating source, thereby preventing the heating device from being damaged due to liquid leakage.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A combined air-cooling and liquid-cooling refrigeration system comprising at least a closed area (1), a combined device group (2) and a circulating liquid-cooling system (3), wherein the combined device group (2) and the circulating liquid-cooling system (3) are installed in the closed area (1);
the combined device group (2) comprises a first device group (21) and a second device group (22), and a closed thermal channel (23) is formed between the first device group (21) and the second device group (22);
the first device group (21) and the second device group (22) each comprise a plurality of air cooling devices (211) and a plurality of heating devices (212); and
the circulating liquid-cooling system (3) is connected to primary heating sources of the plurality of heating devices (212) to carry out liquid-cooling heat dissipation on the primary heating sources of the plurality of heating devices (212), and the plurality of air cooling devices (211) refrigerates hot air discharged from the closed thermal channel (23) to carry out air-cooling heat dissipation on the plurality of heating devices (212).

2. The combined air-cooling and liquid-cooling refrigeration system according to claim 1, wherein the plurality of air-cooling devices (211) and the plurality of heating devices (212) positioned in the same device group are arranged alternately in turn; and
the plurality of air cooling devices (211) of the first device group (21) and the plurality of heating devices (212) of the second device group (22) are arranged opposite to each other.

3. The combined air-cooling and liquid-cooling refrigeration system according to claim 2, wherein the first device group (21) and the second device group (22) are arranged in parallel at intervals; and
partition plates (24) are respectively arranged between two ends of the first device group (21) and the second device group (22), such that the closed thermal channel (23) is formed between the first device group (21), the second device group (22), and the two partition plates (24).

4. The combined air-cooling and liquid-cooling refrigeration system according to claim 3, wherein the circulating liquid-cooling system (3) comprises at least a liquid inlet pipe (31), a liquid outlet pipe (32) and a plurality of liquid-cooling shunts (33);
the liquid inlet pipe (31) and the liquid outlet pipe (32) are connected to an external cooling device to refrigerate circulating liquid in the liquid inlet pipe (31) and the liquid outlet pipe (32);
one end of each of the plurality of liquid-cooling shunts (33) is communicated with the liquid inlet pipe (31), and other end of each of the plurality of liquid-cooling shunts (33) is communicated with the liquid outlet pipe (32); and
each of the plurality of liquid-cooling shunts (33) is connected in series with one end of a heat transfer component (4), and other end of the heat transfer component (4) is in contact with the primary heating source of the heating device (212).

5. The combined air-cooling and liquid-cooling refrigeration system according to claim 4, wherein the heat transfer component (4) comprises at least a heat exchange box (41), a male contact head (42) and a female contact head (43);
the heat exchange box (41) is connected in series with the liquid-cooling shunt (33), such that the circulating liquid in the liquid-cooling shunt (33) flows through an internal cavity of the heat exchange box (41);
the male contact head (42) is connected to the heat exchange box (41), and one end of the male contact head (42) is positioned in the internal cavity of the heat exchange box (41); and
one end of the female contact head (43) is detachably connected to other end of the male contact head (42), and other end of the female contact head (43) is in contact with the primary heating source of the heating device (212).

6. The combined air-cooling and liquid-cooling refrigeration system according to claim wherein the other end of the female contact head (43) is provided with a plurality of heat conduction bars (431), and the plurality of heat conduction bars (431) are respectively connected to at least one of the primary heating sources.

7. The combined air-cooling and liquid-cooling refrigeration system according to claim 6, wherein the circulating liquid-cooling system (3) further comprises a heat exchanger (34); and
the external cooling device exchanges heat with the circulating liquid in the liquid inlet pipe (31) and the liquid outlet pipe (32) through the heat exchanger (34).

8. The combined air-cooling and liquid-cooling refrigeration system according to claim 7, wherein the heat exchanger (34) is provided at one end of the first device group (21) and one end of the second device group (22); and
an array cabinet (35) is provided at other end of the first device group (21) and other end of the second device group (22).

9. The combined air-cooling and liquid-cooling refrigeration system according to claim 1, wherein there are a plurality of the combined device groups (2), and the plurality of combined device groups (2) are arranged in the closed area (1) in a linear array.

10. A data center comprising at least a plurality of device rooms, wherein each of the plurality of device rooms is provided with a combined air-cooling and liquid-cooling refrigeration system, wherein the combined air-cooling and liquid-cooling refrigeration system comprising:
at least a closed area (1), a combined device group (2) and a circulating liquid-cooling system (3), wherein the combined device group (2) and the circulating liquid-cooling system (3) are installed in the closed area (1);
the combined device group (2) comprises a first device group (21) and a second device group (22), and a closed thermal channel (23) is formed between the first device group (21) and the second device group (22);
the first device group (21) and the second device group (22) each comprise a plurality of air cooling devices (211) and a plurality of heating devices (212); and
the circulating liquid-cooling system (3) is connected to primary heating sources of the plurality of heating devices (212) to carry out liquid-cooling heat dissipation on the primary heating sources of the plurality of heating devices (212), and the plurality of air cooling devices (211) refrigerates hot air discharged from the closed thermal channel (23) to carry out air-cooling heat dissipation on the plurality of heating devices (212).

11. The data center according to claim 10, wherein the plurality of air-cooling devices (211) and the plurality of heating devices (212) positioned in the same device group are arranged alternately in turn; and
the plurality of air cooling devices (211) of the first device group (21) and the plurality of heating devices (212) of the second device group (22) are arranged opposite to each other.

12. The data center according to claim 11, wherein the first device group (21) and the second device group (22) are arranged in parallel at intervals; and
partition plates (24) are respectively arranged between two ends of the first device group (21) and the second device group (22), such that the closed thermal channel (23) is formed between the first device group (21), the second device group (22), and the two partition plates (24).

13. The data center according to claim 12, wherein the circulating liquid-cooling system (3) comprises at least a liquid inlet pipe (31), a liquid outlet pipe (32) and a plurality of liquid-cooling shunts (33);
the liquid inlet pipe (31) and the liquid outlet pipe (32) are connected to an external cooling device to refrigerate circulating liquid in the liquid inlet pipe (31) and the liquid outlet pipe (32);
one end of each of the plurality of liquid-cooling shunts (33) is communicated with the liquid inlet pipe (31), and other end of each of the plurality of liquid-cooling shunts (33) is communicated with the liquid outlet pipe (32); and
each of the plurality of liquid-cooling shunts (33) is connected in series with one end of a heat transfer component (4), and other end of the heat transfer component (4) is in contact with the primary heating source of the heating device (212).

14. The data center according to claim 13, wherein the heat transfer component (4) comprises at least a heat exchange box (41), a male contact head (42) and a female contact head (43);
the heat exchange box (41) is connected in series with the liquid-cooling shunt (33), such that the circulating liquid in the liquid-cooling shunt (33) flows through an internal cavity of the heat exchange box (41);
the male contact head (42) is connected to the heat exchange box (41), and one end of the male contact head (42) is positioned in the internal cavity of the heat exchange box (41); and
one end of the female contact head (43) is detachably connected to other end of the male contact head (42), and other end of the female contact head (43) is in contact with the primary heating source of the heating device (212).

15. The data center according to claim 14, wherein the other end of the female contact head (43) is provided with a plurality of heat conduction bars (431), and the plurality of heat conduction bars (431) are respectively connected to at least one of the primary heating sources.

16. The data center according to claim 15, wherein the circulating liquid-cooling system (3) further comprises a heat exchanger (34); and
the external cooling device exchanges heat with the circulating liquid in the liquid inlet pipe (31) and the liquid outlet pipe (32) through the heat exchanger (34).

17. The data center according to claim 16, wherein the heat exchanger (34) is provided at one end of the first device group (21) and one end of the second device group (22); and
an array cabinet (35) is provided at other end of the first device group (21) and other end of the second device group (22).

18. The data center according to claim 10, wherein there are a plurality of the combined device groups (2), and the plurality of combined device groups (2) are arranged in the closed area (1) in a linear array.
